(19) United States
(12) Patent Application Publication
(10) Pub. No.: US 2012/0286397 A1
(43) Pub. Date: Nov. 15, 2012

(54) Die Seal for Integrated Circuit Device

(75) Inventors: Frank Kuechenmeister, Dresden (DE); Matthias Lehr, Dresden (DE)

(73) Assignee: GLOBALFOUNDRIES INC., Grand Cayman (KY)

(21) Appl. No.: 13/107,250

(22) Filed: May 13, 2011

(51) Int. Cl. H01L 23/544; H01L 21/78

(52) U.S. Cl. 257/620; 438/460; 257/773; 257/E23.179

(57) ABSTRACT

Disclosed herein is a semiconductor device having a novel stress reduction structures that are employed in an effort to eliminate or at least reduce undesirable cracking or chipping of semiconductor die. In one example, the device includes a die comprising a semiconducting substrate, wherein the die includes a cut surface. The device also includes a first die seal that defines a perimeter, and at least one stress reducing structure, at least a portion of which is positioned between the perimeter defined by the first die seal and the cut surface, wherein the cut surface exposes at least a portion of the stress reducing structure.

### BACKGROUND OF THE INVENTION

1. Field of the Invention

Generally, the present disclosure generally relates to the manufacturing of sophisticated semiconductor devices, and, more specifically, to a novel die seal for an integrated circuit device.

2. Description of the Related Art

Integrated circuit devices, such as microprocessor, memory chips, application specific integrated circuits, etc., are generally manufactured on semiconducting substrate or wafer, by performing numerous process operations, such as deposition, etching, heat treatment, polishing, etc., until the device is completed. The fabrication of a single integrated circuit device typically involves the formation of millions of semiconductor devices, such as transistors, resistors, capacitors and the like. The fabrication process also involves the formation of many levels of conductive lines and plugs in multiple layers of insulating material to enable transmission of electrical signals to and from the integrated circuit device.

FIG. 1A is a simplified depiction of a plurality of die 20 that may be formed above a semiconducting substrate or wafer. The die 20 are separated by scribe lines 22 that are typically perpendicular to one another. Each of the die 20 contains an integrated circuit device 24 (which is only depicted in the center die 20). Depending upon the sizes of the substrate and the size of the integrated circuit device 24 being manufactured, there may be 50-3000 die formed on a typical 12 inch diameter wafer.

Ultimately, after the integrated circuit devices 24 are formed on the die 20, the die 20 will be separated from one another, packaged and sold. Typically, a diamond blade is used to saw the wafer along the scribe lines 22 to obtain single die 20. However, saw cutting, which typically involves use of a diamond blade, can lead to cracking and chipping of the die 20, particularly in corner areas of the die. Lasers have also been used to separate the die 20, sometimes in combination with traditional saw cutting. However, laser cutting does present some problems, such as incomplete removal of metal by the laser thereby leading to additional contaminates that may adversely impact the performance of the integrated circuit device 24. The use of a laser also results in the formation of a heat affected zone or region adjacent the scribe lines 22, thereby creating a potential for at least more problems. Lastly, the price of a laser cutting system may be 2-3 time higher than that of a diamond blade cutting system.

Since various material layers are formed on the wafer as part of the process of forming the integrated circuit devices 24, the stress caused resulting from die sawing operations may causes the layers of material to crack, chip and/or peel, particularly at the corner region 20A of the die 20, thereby potentially reducing the life or performance of the integrated circuit device 24. This is especially true with more advanced technologies where low-k dielectric materials (k less that 3.5) or ultra-low-k dielectric materials (k less than 3) are used in the integrated circuit device 24 in an effort reduce cross-talk, interconnect RC delays, and power consumption. Such low-k and ultra-low-k materials are generally more brittle and have a lower modulus of elasticity as compared to more traditional dielectric material, such as silicon dioxide. In general, such cracking and chipping is more likely to occur during packaging operations where the die 20 is subjected to numerous process operations that are performed at different temperatures, e.g., during a flip-chip reflow process, during underfill curing, etc.

Typically, one or more die seals are formed on a die 20 in an effort to reduce the adverse effects associated with separating the die 20 by saw cutting processes. For example, the central die 20 depicted in FIG. 1A comprises illustrative first and second die seals 26A, 26B, wherein the first die seal 26A is positioned inside of the second die seal 26B. The integrated circuit device 24 is formed inside of the first die seal 26A. FIG. 1B is a cross-sectional view of the second die seal 26B, taken as indicated in FIG. 1A. FIG. 1C is a cross-sectional view of the first and second dies seals 26A, 26B, taken as indicated in FIG. 1A. In general, the illustrative die seals 26A, 26B depicted in FIGS. 1A-1C, are comprised of a plurality of metal lines 32 and metal plugs 34 that are formed in various layers of insulating material 30 that are formed above an illustrative semiconducting substrate 28. The first and second dies seals 26A, 26B are typically formed at the same time that conductive lines and plugs for the integrated circuit device 24 are formed. Despite the use of such illustrative die seals, the die 20 are subject to cracking and chipping, particularly at the corner region 20A of the die 20.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a novel die seal for an integrated circuit device. In one example, the device includes a die comprising a semiconducting substrate, wherein the die includes a cut surface. The device further includes a first die seal defining a perimeter, and at least one stress reducing structure, at least a portion of which is positioned between the perimeter defined by the first die seal and the cut surface, wherein the cut surface exposes at least a portion of the stress reducing structure.

In another illustrative example, the device includes a semiconducting substrate comprising a plurality of die, wherein adjacent die are separated by scribe lines, and at least one stress reducing structure extending across a scribe line positioned between a pair of adjacent die. In this example, each of the pair of adjacent die comprise a first die seal that defines a perimeter and the portion of the at least one stress reducing structure is positioned between the first die seals on the pair of adjacent die.

A further illustrative method is disclosed herein that involves providing a semiconducting substrate comprising a plurality of die, wherein adjacent die are separated by scribe lines, and forming at least one stress reducing structure across a scribe line that separates two adjacent die. In this illustrative method each of the pair of adjacent die have a first die seal that defines a perimeter and the at least one stress reducing structure is formed such that a portion of the at least one stress reducing structure is positioned between the first die seals on the pair of adjacent die.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C schematically depict an illustrative prior art semiconductor device with a plurality of illustrative die seals; and

FIGS. 2A-2H depict one illustrative example of the novel semiconductor device described herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

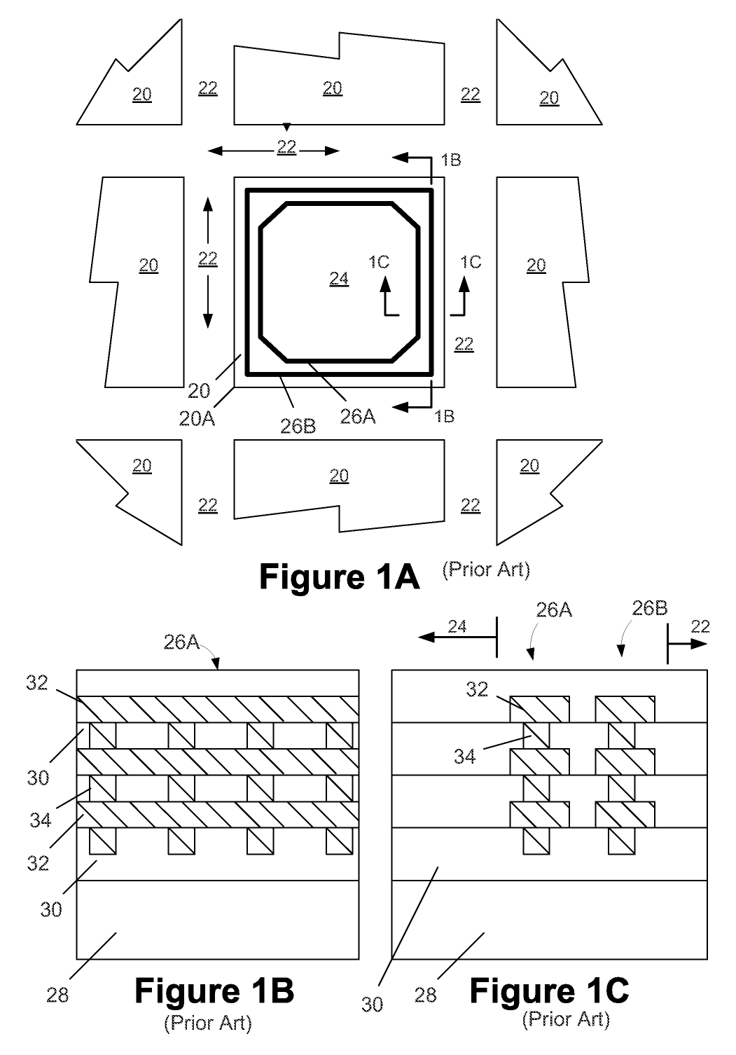

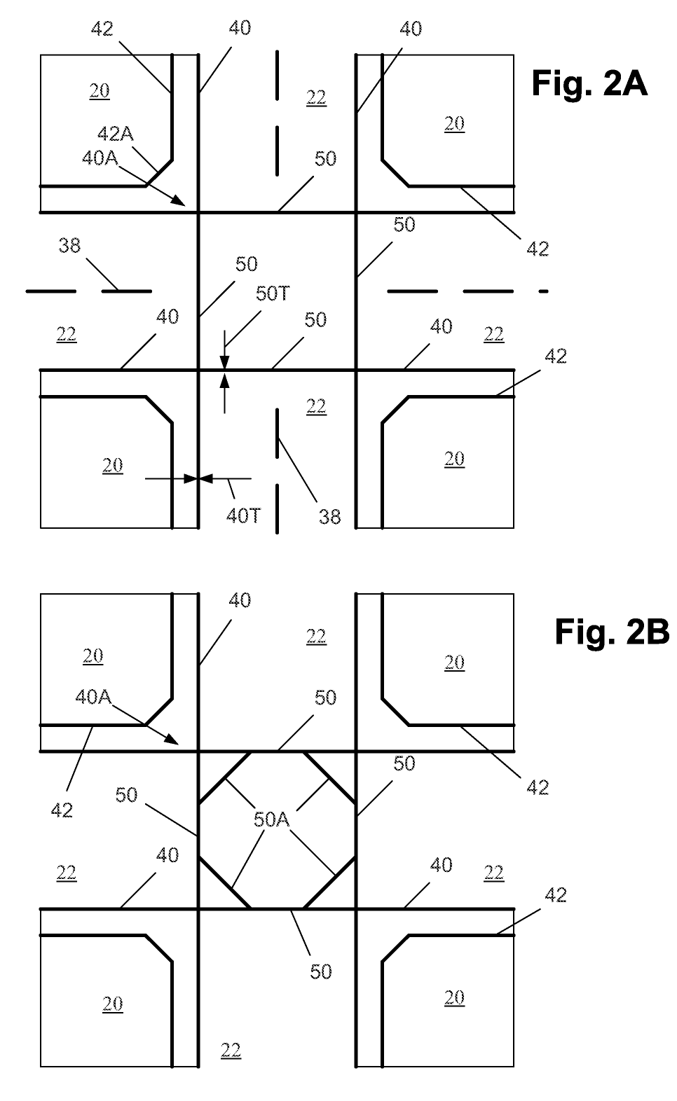

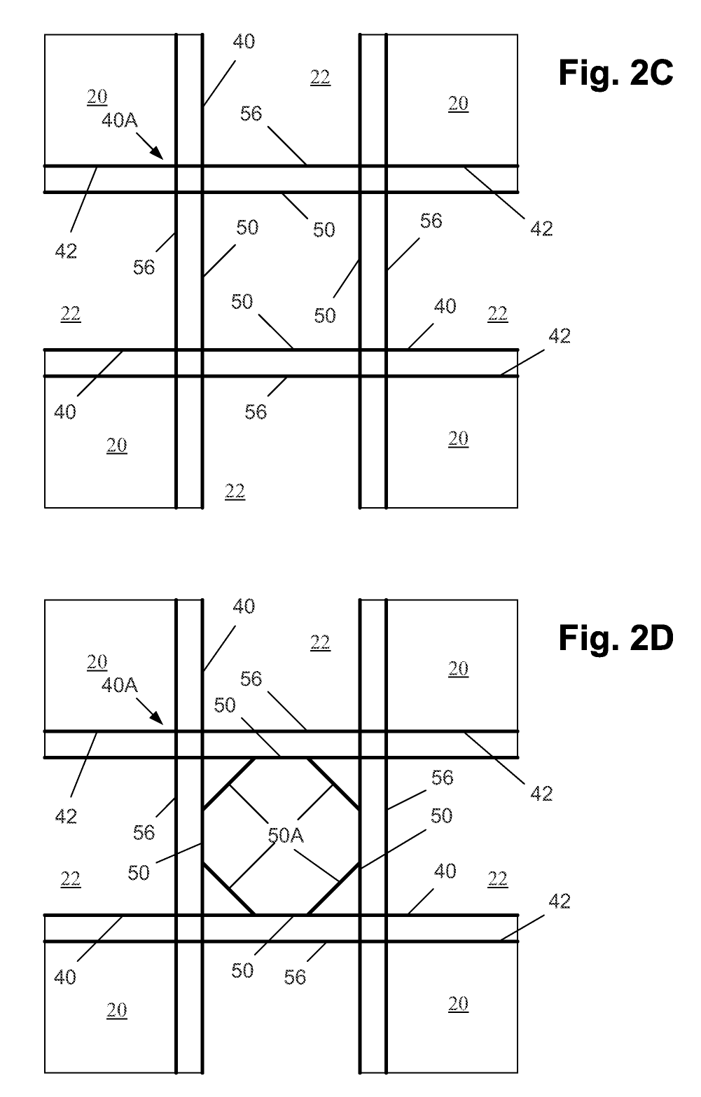

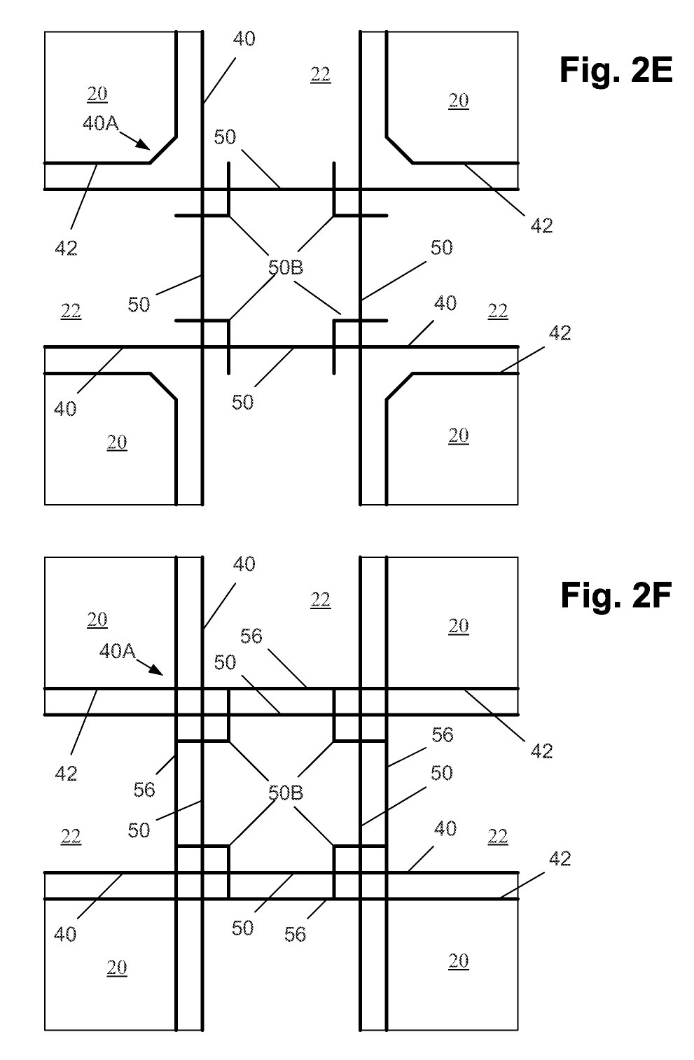

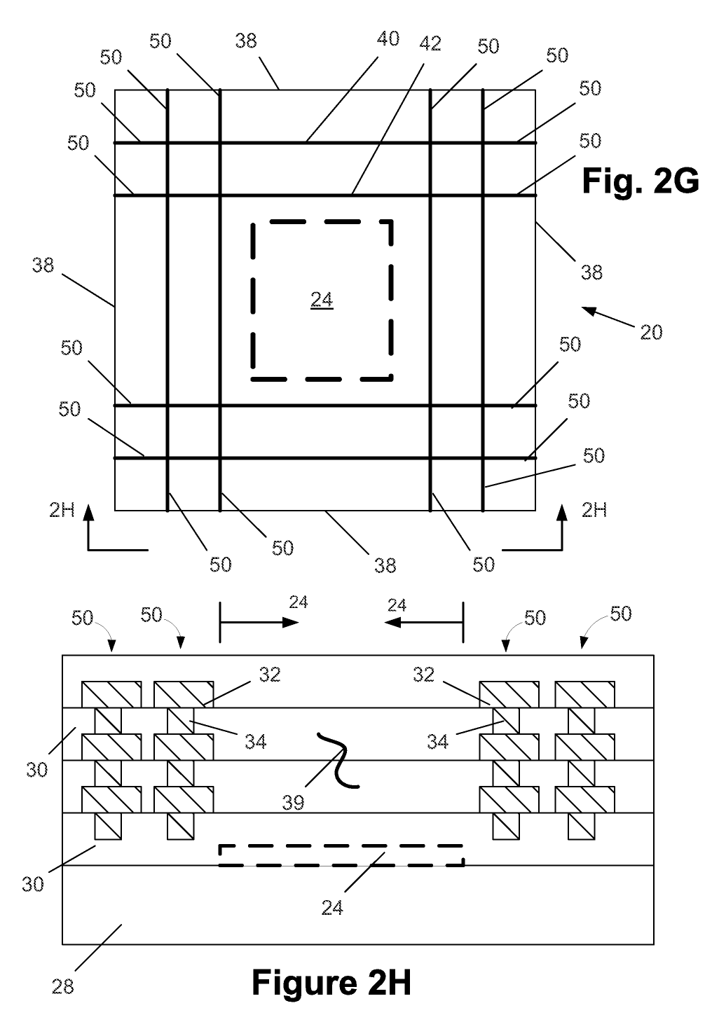

The present disclosure provides is directed to techniques that may be employed in forming die seals on various integrated circuit. As will be readily apparent to those skilled in the art upon a complete reading of the present application, the present method is applicable to a variety of technologies, and is readily applicable to a variety of devices, including, but not limited to, logic devices, memory devices, microprocessors, etc. With reference to FIGS. 2A-2H, further illustrative embodiments will now be described in more detail, wherein reference may also be made to FIGS. 1A-1C, if required. To the extent that the same numbers are used in FIGS. 2A-2H to describe certain structure, the previous description provided will apply equally to the description of the devices shown in FIGS. 2A-2H.

FIG. 2A depicts a plurality of die 20 separated by scribe lines 22. The die 20 are formed above a semiconducting substrate (not shown in FIGS. 2A-2H). In one illustrative embodiment, the semiconducting substrate may be a silicon-on-insulator (SOI) substrate comprised of bulk silicon, a buried insulation layer (commonly referred to as a “BOX” layer) and an active layer, which may also be a silicon material. Of course, the present invention may also be employed when the substrate is made of semiconducting materials other than silicon and/or it may be in another form, such as a bulk silicon configuration. Thus, the terms substrate or semiconductor substrate should be understood to cover all forms of semiconductor structures.

Also depicted in FIG. 2A are schematically depicted intended cut lines 38 for a future cutting process that will be performed to separate the die 20. The intended cut lines 38 are not shown in subsequent drawings for purposes of clarity. The cutting process used to separate the die 20 may be of any type, e.g., saw cutting or a laser cutting process, or combinations of both. Any of a variety of types of integrated circuit devices 24 (not shown in FIGS. 2A-2H) may be formed on the die 20. Also depicted in FIG. 2A is an illustrative outer die seal ring 40 and an illustrative inner die seal ring 42 that is formed inside the perimeter defined by the outer die seal ring 40. In the illustrative embodiment depicted in FIG. 2A, the inner die seal ring 42 has a chamfer 42A, while the illustrative outer die seal ring 40 has a generally rectangular or square corner configuration 40A. As will be recognized by those skilled in the art after a complete reading of the present application, the number, size and configuration of the illustrative seal rings 40, 42 disclosed herein may vary depending upon the particular application. For example, the outer and inner die seal rings 40, 42, may consist of a plurality of metal lines and plugs, similar to those depicted in FIGS. 1B, 1C. The overall vertical height of the outer and inner die seal rings 40, 42 may also vary depending upon the particular application, e.g., they may have a height that extends from the first to the last metallization layer for the semiconductor device 24. The number of seal rings on a die 20 may also vary. For example, in some embodiments, the die 20 may not include the inner die seal ring 42. Additionally, while the illustrative outer die seal ring 40 depicted in the drawings has a generally rectangular or square overall configuration, such a configuration is not required in all cases and such illustrative configurations should not be considered a limitation of the present invention.

Also depicted in FIG. 2A are a plurality of stress reducing structures 50 that, in the illustrative example depicted in FIG. 2A, extend across the scribe line 22 between adjacent die 20. The stress reducing features 50 are, in effect, structures employed to reduce or stop cracking and chipping of the die 20 at, for example, the corner region of the die 20. Thus, the phrase “stress reducing feature” is merely a shorthand reference for the various structures disclosed herein. More specifically, the stress reducing structures 50 extend from the outer perimeter defined by the outer die seal 40 on a first die 20 to the outer perimeter defined by the outer perimeter defined by the outer die seal on a second die 20. However, contact between the stress reducing structures 50 and one or more of the outer die seals 40 on the various die 20 may or may not be required in all applications.

FIGS. 2B-2F depict various illustrative configurations and locations for the stress reducing structures 50 described herein. For example, in FIG. 2B a plurality of chamfer stress reducing structures 50A are formed in the scribe lines 22 within the interior of the perimeter defined by the stress reducing structures 50 depicted in FIG. 2A. However, contact between the stress reducing structures 50A and one or more of the stress reducing structures 50 is not required in all applications.

FIG. 2C depicts an illustrative example where multiple stress reducing structures 50 are formed that extend from the outer perimeter defined by the outer die seal 40 on a first die 20 to the outer perimeter defined by the outer die seal 40 on a second die 20. However, as noted earlier, physical contact between the stress reducing structures 50 and one or more of the outer die seals 40 on the various die 20 may not be required in all applications. More-over, the general parallel relationship between adjacent stress reducing structures 50 depicted in FIG. 2C need not exist in all applications.

FIG. 2D depicts an illustrative example wherein a plurality of chamfer stress reducing structures 50A are formed in the scribe lines 22 within the interior of the perimeter defined by the intersecting inner-most stress reducing structures 50 depicted in FIG. 2D. However, as noted earlier, contact between the chamfer stress reducing structures 50A and one or more of the stress reducing structures 50 may not be required in all applications.

FIG. 2E depicts an illustrative example wherein a plurality of corner-shaped stress reducing structures 50B are formed in the scribe lines 22 of the substrate. In this example the corner-shaped stress reducing structures 50B have been added to the structures depicted in FIG. 2A. As depicted, the corner-shaped stress reducing structures 50B extend across a pair of stress reducing structures 50. In one particular example, the corner-shaped stress reducing structures 50B are configured to be similar to the configuration of the corner region 40A of the outer die seal 40. As noted earlier, contact between the corner-shaped stress reducing structures 50B and one or more of the stress reducing structures 50 may not be required in all applications.

FIG. 2F depicts an illustrative example wherein a plurality of the corner-shaped stress reducing structures 50B have been added to the structures depicted in FIG. 2A. In this illustrative embodiment, each leg of the corner-shaped stress reducing structures 50B extends across one of the stress reducing structures 50 and abuts or contacts another of the stress reducing structures 50. In this example, the corner-shaped stress reducing structures 50B also have a configuration that is similar to the configuration of the corner region 40A of the outer die seal 40. As noted earlier, contact between the corner-shaped stress reducing structures 50B and one or more of the stress reducing structures 50 may not be required in all applications.

The illustrative stress reducing structures 50, 50A and/or 50B depicted herein, alone or in various combinations, may tend to reduce the stress present at least in the immediate area outside the corner region 40A of the outer die seal 40 on the die 20, thereby tending to reduce the chances of cracks propagating into the interior of the die 20. In general, the stress reducing structures 50, 50A, and/or 50B, may have a size and/or configuration that is the same or different than the size and configuration of the structures that define the outer die seal 40 and/or the inner die seal 42. For example, as shown in FIG. 2A, when viewed for the top, the thickness 50T of one or more of the stress reducing structures 50 outside of the perimeter defined by the outer die seal 40 may be same as the thickness 40T of the structures used to define the outer die seal 40. As a specific illustrative example, the thickness 40T may be approximately 3-30 μm whereas the thickness 50T may be approximately 3-30 μm. In other examples, if desired, the thicknesses 40T and 50T may be different, e.g., the thickness 50T may be greater than the thickness 40T. As another example, the thickness of the corner-shaped stress reducing structures 50B may be the same or different as the thickness 50T of the stress reducing structures 50. In some cases, the stress reducing structures 50, 50A and/or 50B, may be manufactured at the same time as the structures that define the outer die seal 40 and/or inner die seal 42 are manufactured. In other situations, the stress reducing structures 50, 50A, and/or 50B may be manufactured completely independently of the manufacture of the structures that define the outer die seal 40 and/or inner die seal 42. In one particularly illustrative example, the stress reducing structures 50, 50A, and 50B each have the same size and configuration as the as the structures that define the outer die seal 40 and/or inner die seal 42, and the stress reducing structures 50, 50A, and 50B that extend beyond the perimeter defined by the outer die seal 40 are extensions of structures that define the outer die seal 40.

FIG. 2G depicts an illustrative individual die 20 after it has been separated from the other die on a wafer by performing, for example, a saw cutting operation along the cut lines 38 depicted in FIG. 2A. In this particular example, the die 20 comprises outer and inner die seals 40, 42 as well as a plurality of stress reducing structures 50 that are configured as depicted in FIG. 2C. Also depicted in FIG. 2G is an illustrative semiconductor device 24 (shown in dashed lines). FIG. 2H is a side view of the die 20 depicted in FIG. 2G. As can be seen in FIG. 2H, the stress reducing structures 50 are formed from of a plurality of interconnected metal lines 32 and metal plugs 34 that are formed in various layers of insulating material 30. Importantly, portions of the stress reducing structures 50 lie in or are exposed by the cut surface 39 of the die 20 (defined by cutting along the cut lines 38). The cut surface 39 may be defined by performing one or more dicing operations such as a saw cutting operation or a laser cutting operation, or a combination of both, to separate the plurality of die 20. In the example depicted in FIG. 2H, the cut surface 39 extends through the illustrative metal lines 32 and metal plugs 34. However, depending upon the location of the cut lines 38 relative to the position of the metal plugs 34, the cut surface may only contain or expose the metal line portions 32 of the stress reducing structures 50. By providing one or more of the stress reducing structures 50, 50A, and/or 50B, or combinations thereof on a die 20 in an area or region that is beyond the perimeter defined by the outer die seal 40 but, in one embodiment, extends to the cut surface 39 of the die 20, the cracking and/or chipping of the various layers that make up the semiconductor device 24 positioned on the die 20.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a die comprising a semiconducting substrate, said die comprising a cut surface;
a first die seal defining a perimeter; and
at least one stress reducing structure, at least a portion of which is positioned between said perimeter defined by said first die seal and said cut surface, wherein said cut surface exposes at least a portion of said stress reducing structure.

2. The device of claim 1, wherein said device further comprises a second die seal positioned within said perimeter defined by said first die seal, and wherein said first die seal is an outer die seal.

3. The device of claim 1, wherein said at least one stress reducing structure is comprised of a plurality of metal lines and metal plugs positioned in a plurality of insulating material layers.

4. The device of claim 1, wherein said first die seal and said at least one stress reducing structure are each comprised of a plurality of metal lines and metal plugs positioned in a plurality of insulating material layers and wherein said first die seal and said at least one stress reducing structure have the same configuration.

5. The device of claim 1, wherein said first die seal and said at least one stress reducing structure are each comprised of a plurality of metal lines and metal plugs positioned in a plurality of insulating material layers and wherein said first die seal and said at least one stress reducing structure have a different configuration.

6. The device of claim 5, wherein a horizontal thickness of at least said metal lines that comprise said first die seal is different than a horizontal thickness of at least said metal lines that comprise said at least one stress reducing structure.

7. The device of claim 6, wherein said horizontal thickness of at least said metal lines that comprise said first die seal is less than a horizontal thickness of at least said metal lines that comprise said at least one stress reducing structure.

8. A device, comprising:
a die comprising a semiconducting substrate, said die comprising a cut surface;
a first outer die seal defining a perimeter;
a second inner die seal positioned within said perimeter defined by said first outer die seal; and
at least one stress reducing structure, at least a portion of which is positioned between said perimeter defined by said first outer die seal and said cut surface, wherein said at least one stress reducing structure is comprised of a plurality of metal lines and metal plugs positioned in a plurality of insulating material layers and wherein said cut surface exposes at least a portion of said metal lines.

9. The device of claim 8, wherein said first outer die seal is also comprised of said plurality of metal lines and said plurality of metal plugs, and wherein said first out die seal and said at least one stress reducing structure have the same configuration.

10. The device of claim 8, wherein said first outer die seal and said at least one stress reducing structure have a different configuration.

11. A device, comprising:
a semiconducting substrate comprising a plurality of die, wherein adjacent die are separated by scribe lines; and
at least one stress reducing structure extending across a scribe line positioned between a pair of adjacent die, wherein each of the pair of adjacent die comprise a first die seal that defines a perimeter and wherein said at least a portion of said at least one stress reducing structure is positioned between said first die seals on said pair of adjacent die.

12. The device of claim 11, wherein said at least one stress reducing structure contacts said first die seal on each of said pair of adjacent die.

13. The device of claim 11, wherein said at least one stress reducing structure comprises a plurality of said stress reducing structures and wherein each of said plurality of stress reducing structures extend across a scribe line positioned between said pair of adjacent die.

14. The device of claim 11, wherein said at least one stress reducing structure is comprised of a plurality of metal lines and metal plugs positioned in a plurality of insulating material layers.

15. The device of claim 11, wherein said first die seal and said at least one stress reducing structure are each comprised of a plurality of metal lines and metal plugs positioned in a plurality of insulating material layers and wherein said first die seal and said at least one stress reducing structure have the same configuration.

16. The device of claim 11, wherein said first die seal and said at least one stress reducing structure are each comprised of a plurality of metal lines and metal plugs positioned in a plurality of insulating material layers and wherein said first die seal and said at least one stress reducing structure have a different configuration.

17. A method, comprising:
providing a semiconducting substrate comprising a plurality of die, wherein adjacent die are separated by scribe lines; and
forming at least one stress reducing structure across a scribe line that separates two adjacent die, wherein each of the pair of adjacent die comprise a first die seal that defines a perimeter and wherein said at least a portion of said at least one stress reducing structure is positioned between said first die seals on said pair of adjacent die.

18. The method of claim 17, further comprising performing at least one dicing operation to separate said plurality of die, wherein said dicing operations results in cut surface between said pair of adjacent die, at least a portion of said stress reducing structure being exposed by said cut surface.

19. The method of claim 18, wherein said at least one dicing operation comprises performing one of a sawing operation or a laser cutting operation.

20. The method of claim 17, wherein forming said at least one stress reducing structure comprises forming a plurality of metal lines and a plurality of metal plugs in a plurality of insulating material layers.
